(19) United States
(12) Patent Application Publication
(10) Pub. No.: US 2018/0270985 A1
(43) Pub. Date: Sep. 20, 2018

(54) POWER SUPPLY RELAY UNIT

(71) Applicant: FUJI ELECTRIC CO., LTD., Kawasaki-shi (JP)

(72) Inventor: Yuushi SHIRAGA, Suzuka-shi (JP)

(21) Appl. No.: 15/987,350

(22) Filed: May 23, 2018

Related U.S. Application Data
(63) Continuation of application No. PCT/JP2017/001466, filed on Jan. 18, 2017.

(30) Foreign Application Priority Data
Jun. 7, 2016 (JP) 2016-113262

(51) Int. Cl. H05K 7/14; G06F 1/26; G06F 1/20; H05K 7/20; H02H 7/20

(52) U.S. Cl. CPC H05K 7/1492; G06F 1/26; G06F 1/20; H02H 1/0007; H05K 7/1489; H02H 7/20; H05K 7/20727; H05K 7/20909

(57) ABSTRACT

This power supply relay unit includes a power supply relay unit main body including a first switch and a resistor, and the power supply relay unit main body is disposed inside a load through which cooling air generated by a cooling fan flows.

### CROSS-REFERENCE TO RELATED APPLICATION

This application is a continuation of PCT application PCT/JP2017/001466, filed on Jan. 18, 2017, which is based upon and claims priority of Japanese patent application No. 2016-113262, filed on Jun. 7, 2016, the entire contents of which are incorporated herein by reference.

### BACKGROUND OF THE INVENTION

### Field of the Invention

The present invention relates to a power supply relay unit, and more particularly, it relates to a power supply relay unit provided between a power supply and a load.

### Description of the Background Art

In general, a power supply unit provided between a power supply and a load is known. Such a power supply unit is disclosed in International Publication No. WO2015/087437.

International Publication No. WO2015/087437 discloses a power converter provided between an AC power supply and an AC motor. This power converter includes a forward converter that converts AC power into DC power and a reverse converter that converts DC power into AC power having an arbitrary frequency. In the reverse converter, a switching device (semiconductor device) is provided. In this power converter, a shunt resistor configured to detect a current that flows through the switching device of the reverse converter is provided. In this power converter, a cooling fan configured to cool the forward converter and a power module (the switching device, for example) in the reverse converter is further provided.

However, in the power converter disclosed in International Publication No. WO2015/087437, the cooling fan configured to cool the switching device etc. is provided, and hence the size of the power converter is disadvantageously increased.

### SUMMARY OF THE INVENTION

The present invention has been proposed in order to solve the aforementioned problem, and one object of the present invention is to provide a power supply relay unit capable of suppressing an increase in size while performing cooling.

In order to attain the aforementioned object, a power supply relay unit according to an aspect of the present invention is provided between a DC power supply including a power supply unit that converts AC power into DC power and a battery unit that stores the DC power obtained by conversion by the power supply unit, and a load including a cooling fan, and includes a power supply relay unit main body including a first switch to which the DC power from the DC power supply is input and a resistor provided between the DC power supply and the first switch and configured to detect a current that flows from the DC power supply to the first switch. The power supply relay unit main body is disposed inside the load through which cooling air generated by the cooling fan flows, and the power supply relay unit further includes a main substrate on which the first switch and the resistor are disposed, and an auxiliary substrate on which an electronic element that generates less heat than the first switch and the resistor is disposed.

In the power supply relay unit according to this aspect of the present invention, as hereinabove described, the power supply relay unit main body is disposed inside the load through which the cooling air generated by the cooling fan flows. Thus, even when the cooling fan is not provided in the power supply relay unit main body, the first switch and the resistor of the power supply relay unit main body can be cooled by the cooling air generated by the cooling fan included in the load. Consequently, it is not necessary to provide the cooling fan in the power supply relay unit main body, and hence it is possible to suppress an increase in the size of the power supply relay unit. That is, even when a space in which the power supply relay unit is disposed is limited in size, the power supply relay unit that matches the size of the space can be formed while the power supply relay unit is cooled.

Furthermore, FIT (average failure rate per unit time) of the cooling fan is relatively large compared with those of the first switch and the resistor. That is, the cooling fan is relatively more likely to fail than the first switch and the resistor. Therefore, the cooling fan is not provided in the power supply relay unit such that it is possible to suppress shortening of the lifetime of the power supply relay unit due to the failure of the cooling fan. In other words, the cooling fan, which is relatively more likely to fail, is not provided in the power supply relay unit, and hence the reliability of the power supply relay unit can be improved.

The aforementioned power supply relay unit according to this aspect preferably further includes a housing that covers the first switch and the resistor, and the housing preferably includes a hole through which the cooling air generated by the cooling fan is taken. According to this configuration, the cooling air generated by the cooling fan can be easily taken into the housing through the hole of the housing.

In this case, the hole is preferably provided in a side surface of the housing on a first end side and a side surface of the housing on a second end side in a direction in which the first switch and the resistor are disposed. According to this configuration, the cooling air taken from the side surface of the housing on the first end side is discharged from the side surface of the housing on the second end side to the outside of the housing via the first switch and the resistor, and hence the first switch and the resistor can be effectively cooled.

In the aforementioned power supply relay unit including the housing, the housing is preferably box-shaped, a gap through which the cooling air passes is preferably provided between an inner upper surface of the box-shaped housing and a front surface of the main substrate on which the first switch and the resistor are disposed, and a gap through which the cooling air passes is preferably provided between an inner lower surface of the box-shaped housing and a back surface of the main substrate. According to this configuration, the cooling air taken into the housing flows over both the front surface and the back surface of the main substrate, and hence the first switch and the resistor disposed on the main substrate can be efficiently cooled.

The aforementioned power supply relay unit according to this aspect preferably further includes a power supply relay unit-side connection directly connected to a load-side connection included in the load and connectable to a load-side power supply unit that converts AC power into DC power. According to this configuration, the power supply relay unit is directly connected to the load-side connection by the power supply relay unit-side connection, and hence the power supply relay unit can be easily disposed inside the load. Consequently, the cooling air generated by the cooling fan of the load is easily taken into the power supply relay unit.

In the aforementioned power supply relay unit according to this aspect, the auxiliary substrate is preferably disposed on a front surface of the main substrate so as to be substantially perpendicular to the front surface of the main substrate and along flow of the cooling air. According to this configuration, the surface area of the power supply relay unit (main substrate) can be reduced unlike the case where all electronic elements are disposed on the main substrate. Furthermore, the auxiliary substrate is disposed on the front surface of the main substrate so as to be substantially perpendicular to the front surface of the main substrate and along the flow of the cooling air, and hence it is possible to suppress obstruction of the flow of the cooling air by the auxiliary substrate. That is, the cooling air can smoothly flow over the front surface of the main substrate on which the first switch and the resistor that generate a relatively large amount of heat are disposed. Thus, it is possible to suppress a reduction in the cooling efficiency of the cooling air.

In this case, the power supply relay unit preferably further includes a second switch disposed on the main substrate and turned on to supply a first current to the load and activate a load-side controller of the load, the first switch is preferably configured to, after the load-side controller of the load is activated, be turned on based on a request signal from the load-side controller of the load for requesting power supply to supply a second current larger than the first current to the load, and the auxiliary substrate is preferably disposed on the front surface of the main substrate so as to partition the first switch from the second switch. According to this configuration, the auxiliary substrate can suppress heat transfer to the second switch from the first switch that generates a large amount of heat due to the relatively large second current flowing therethrough.

In the aforementioned power supply relay unit according to this aspect, the power supply relay unit main body is preferably disposed inside a server as the load through which the cooling air generated by the cooling fan flows. According to this configuration, the cooling fan is provided in advance in the server as the load, and hence the first switch and the resistor of the power supply relay unit can be cooled by the cooling fan provided in advance.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram of server systems (DC power supplies, power supply relay units, servers) according to an embodiment of the present invention;

FIG. 2 is a diagram showing a server system disposed in a server rack;

FIG. 3 is a block diagram of a power supply relay unit according to the embodiment of the present invention;

FIG. 4 is a diagram showing a cooling fan and the power supply relay unit disposed in a server according to the embodiment of the present invention;

FIG. 5 is an exploded perspective view of the power supply relay unit according to the embodiment of the present invention;

FIG. 6 is a diagram of the power supply relay unit according to the embodiment of the present invention, as viewed from an X1 side;

FIG. 7 is a diagram of the power supply relay unit according to the embodiment of the present invention, as viewed from an X2 side;

FIG. 8 is a diagram showing a main substrate of the power supply relay unit according to the embodiment of the present invention;

FIG. 9 is a diagram (1) showing an auxiliary substrate of the power supply relay unit according to the embodiment of the present invention; and

FIG. 10 is a diagram (2) showing the auxiliary substrate of the power supply relay unit according to the embodiment of the present invention.

### DESCRIPTION OF THE PREFERRED EMBODIMENTS

Embodiments embodying the present invention are hereinafter described on the basis of the drawings.

### Present Embodiment

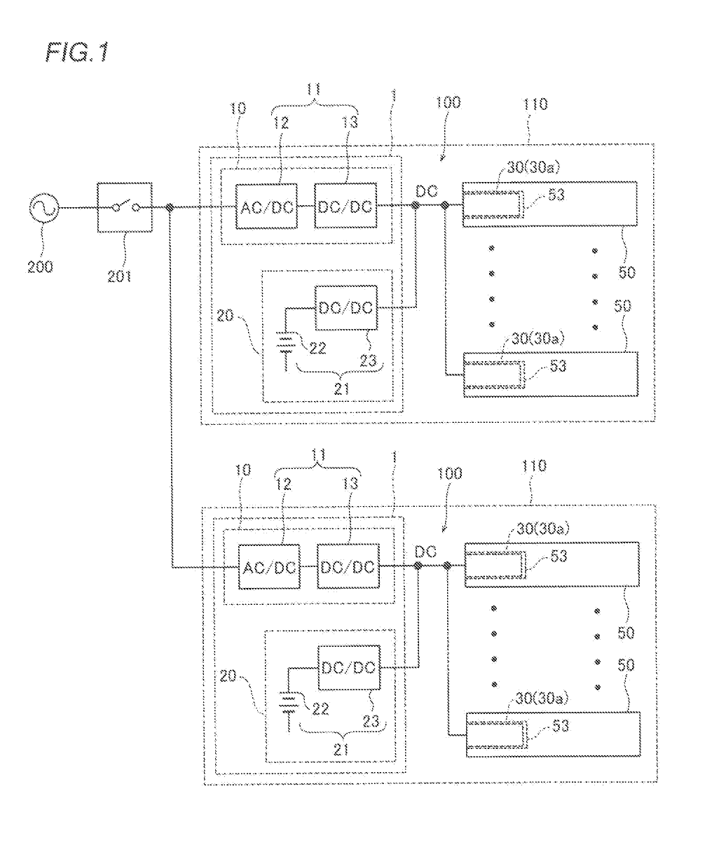

The configuration of a DC power supply system 100 (power supply relay units 30) according to the present embodiment is described with reference to FIGS. 1 to 10.

### Configuration of DC Power Supply System

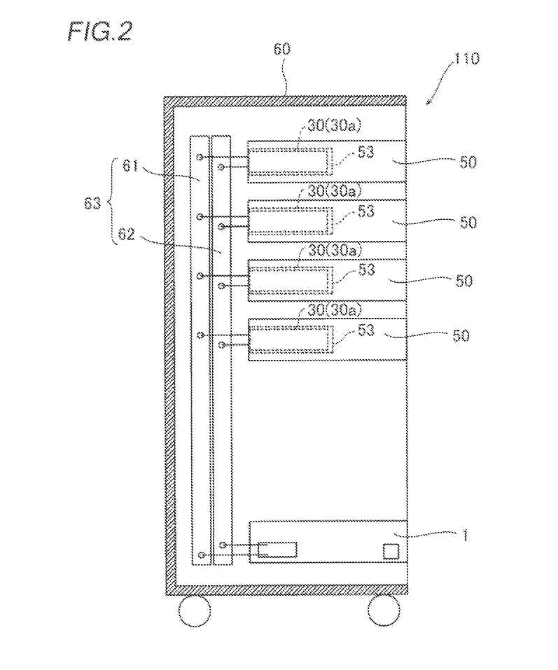

First, the schematic configuration of the DC power supply system 100 is described with reference to FIGS. 1 and 2. As shown in FIG. 1, the DC power supply system 100 includes a DC power supply 1 and the power supply relay units 30. The DC power supply system 100 is configured to convert AC power supplied from an AC power supply 200 into DC power and supply the DC power to a plurality of servers 50. The servers 50 are examples of a “load” in the claims.

The servers 50 each include a general AC server driven by converting input AC power into DC power. In a general AC server, a power supply unit (server-side power supply unit) (not shown) that converts AC power into DC power is provided. On the other hand, the servers 50 according to the present embodiment each include one obtained by removing the server-side power supply unit that converts AC power into DC power from the general existing AC server.

Furthermore, a DC power distribution device 201 is provided between the AC power supply 200 and the DC power supply system 100.

A plurality of sets (server systems 110) of the DC power supply 1, the power supply relay units 30, and the servers 50 are provided. The plurality of server systems 110 is connected in parallel to each other. That is, the DC power supply 1 is provided in each of the plurality of server systems 110. Thus, unlike the case where one DC power supply 1 is provided for the plurality of server systems 110, even if one of a plurality of DC power supplies 1 fails, it is possible to suppress stop of all the server systems 110.

### Configuration of DC Power Supply

The DC power supply 1 includes a power supply unit 10 that converts AC power into DC power and a battery unit 20 that stores the DC power obtained by conversion by the power supply unit 10. The power supply unit 10 includes a power supply circuit 11. The power supply circuit 11 includes an AC-DC converter 12 and a DC-DC converter 13. The AC power supplied from the AC power supply 200 is converted into DC power by the AC-DC converter 12. The DC power obtained by conversion by the AC-DC converter 12 is converted into DC power having a predetermined voltage by the DC-DC converter 13. The DC power, the voltage of which has been converted into the predetermined voltage by the DC-DC converter 13, is supplied to the servers 50.

The battery unit 20 includes a battery circuit 21. The battery circuit 21 includes a battery 22 charged with DC power and a DC-DC converter 23 that bi-directionally conducts DC power. The battery 22 is connected in parallel to the power supply circuit 11 via the DC-DC converter 23 capable of bi-directionally conducting DC power. Furthermore, the battery 22 is charged with DC power by the power supply circuit 11 via the DC-DC converter 23, and supplies the charged DC power to the servers 50 via the DC-DC converter 23. That is, the DC power supply 1 normally supplies DC power from the power supply circuit 11 to the servers 50, and supplies DC power from the battery circuit 21 to the servers 50 when DC power is not supplied from the power supply circuit 11, such as in the event of a power failure.

As shown in FIG. 2, the DC power supply 1 and the plurality of servers 50 are disposed in a server rack 60. The DC power supply 1 is disposed in a lower portion of the server rack 60. The plurality of servers 50 is disposed above the DC power supply 1. In the server rack 60, a conductor 63 including a positive electrode conductor 61 and a negative electrode conductor 62 is provided. The power supply relay units 30 are electrically connected to the conductor 63. In addition, the plurality of servers 50 is connected in parallel to the conductor 63. The DC power output from the DC power supply 1 is supplied to the plurality of servers 50 via the conductor 63 and the power supply relay units 30.

As shown in FIG. 2, a plurality of power supply relay units 30 is provided so as to correspond to the plurality of servers 50. Specifically, in one server system 110, one DC power supply 1 and the plurality of servers 50 are provided. One (or more) power supply relay unit 30 is provided in each of the plurality of servers 50.

### Circuit Configuration of Power Supply Relay Unit

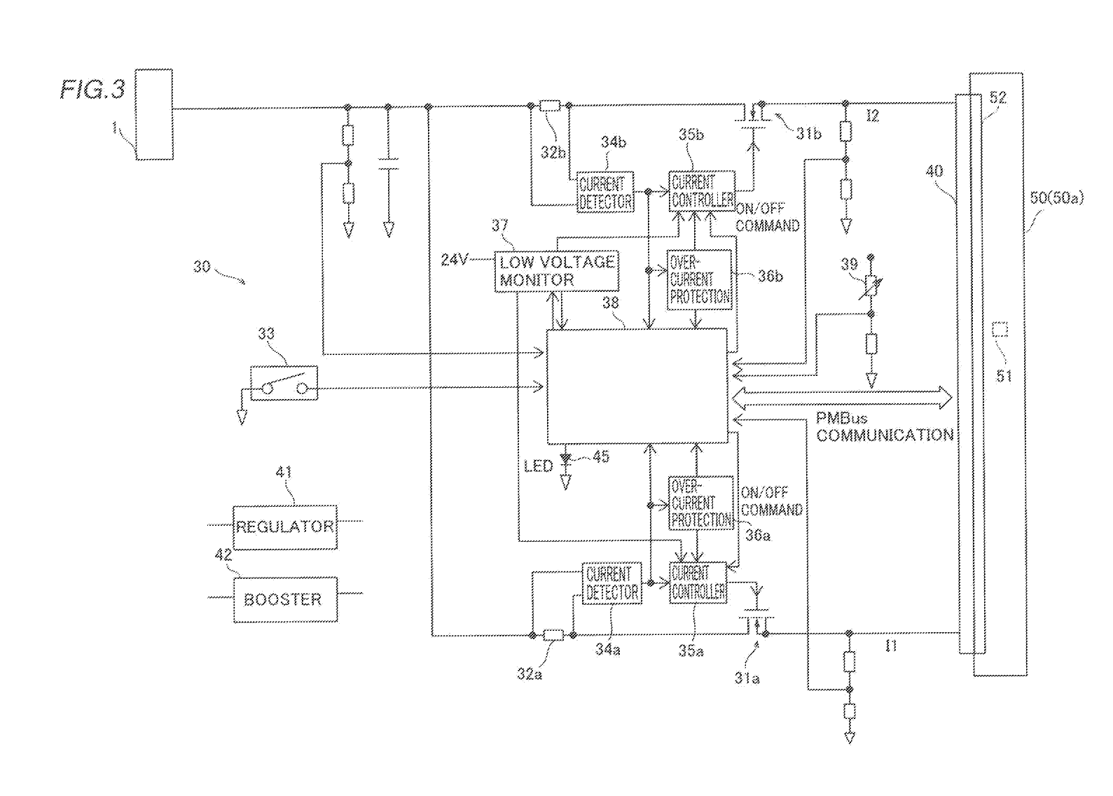

Next, the circuit configuration of one of the power supply relay units 30 according to the present embodiment is described with reference to FIG. 3.

As shown in FIG. 3, the power supply relay unit 30 includes a switch 31a. The switch 31a is configured to receive the DC power from the DC power supply 1 via a shunt resistor 32a. The switch 31a is configured to be turned on to supply a current I1 of 12 V and 2 A, for example, to one of the servers 50 (server main body 50a) and activate a server-side controller 51 of the server 50. The switch 31a is an example of a “second switch” in the claims. The current I1 is an example of a “first current” in the claims. The server-side controller 51 is an example of a “load-side controller” in the claims.

The switch 31a includes an FET (Field Effect Transistor), for example. The shunt resistor 32a is connected to a drain of the switch 31a, and a connection 40 described later is connected to a source thereof. A current controller 35a described later is connected to a gate of the switch 31a. The connection 40 is an example of a “power supply relay unit-side connection” in the claims.

The power supply relay unit 30 further includes a switch 33. The switch 33 includes a mechanical switch, for example. The switch 33 is configured to be turned on to turn on the switch 31a. Specifically, after a signal indicating that the switch 33 has been turned on is input to a controller 38, a signal for turning on the switch 31a is output from the controller 38.

The power supply relay unit 30 further includes a switch 31b. The switch 31b is configured to receive the DC power from the DC power supply 1 via a shunt resistor 32b. The switch 31b is configured to, after the server-side controller 51 of the server 50 is activated, be turned on based on a request signal from the server-side controller 51 of the server 50 for requesting power supply to supply a current I2 of 12 V and 100 A, for example, larger than the current I1 to the server 50. Specifically, after the request signal from the server-side controller 51 of the server 50 for requesting power supply, including a command based on the PMBus (registered trademark) standard is input to the controller 38, a signal for turning on the switch 31b is output from the controller 38. The switch 31b is an example of a “first switch” in the claims. The current I2 is an example of a “second current” in the claims. The shunt resistor 32b is an example of a “resistor” in the claims.

The switch 31b includes an FET (Field Effect Transistor), for example. The connection 40 described later is connected to a source of the switch 31b, and the shunt resistor 32b is connected to a drain thereof. That is, the switch 31b and the shunt resistor 32b are provided between the DC power supply 1 and the server 50. A current controller 35b described later is connected to a gate of the switch 31b. The switch 31a and the switch 31b are connected in parallel to each other.

In addition, a current detector 34a is provided at both ends of the shunt resistor 32a. A current detector 34b is also provided at both ends of the shunt resistor 32b. The shunt resistors 32a and 32b (current detectors 34a and 34b) are configured to detect a current value of a current that flows through the server 50. A signal from the current detector 34a is output to the current controller 35a, an overcurrent protection 36a, and the controller 38. A signal from the current detector 34b is output to the current controller 35b, an overcurrent protection 36b, and the controller 38.

On the output side of the current detector 34a, the current controller 35a is provided. The current controller 35a is configured to output a signal to the gate of the switch 31a. On the output side of the current detector 34b, the current controller 35b is provided. The current controller 35b is configured to output a signal to the gate of the switch 31b. The current controller 35a is configured to gently turn on the switch 31a. The current controller 35b is configured to gently turn on the switch 31b. When the switches 31a and 31b are abruptly turned on, the switches 31a and 31b may be damaged due to a large inrush current for charging a load capacitor (not shown) on the server 50 side. Therefore, the switches 31a and 31b are gently turned on.

Signals from the current detector 34a, the overcurrent protection 36a, the controller 38, and a low voltage monitor 37 are input to the current controller 35a. Signals from the current detector 34b, the overcurrent protection 36b, the controller 38, and the low voltage monitor 37 are input to the current controller 35b.

On the output side of the current detector 34a, the overcurrent protection 36a is provided. The signal from the overcurrent protection 36a is output to the current controller 35a and the controller 38. On the output side of the current detector 34b, the overcurrent protection 36b is provided. The signal from the overcurrent protection 36b is output to the current controller 35b and the controller 38. The overcurrent protections 36a and 36b are configured to suppress damages of the switches 31a and 31b due to short-circuit currents when the output of the switch 31a, which is a sub output, and the output of the switch 31b, which is a main output, are short-circuited. When the overcurrent protections 36a and 36b are configured by software, there are cases where it is not possible to suppress damages of the switches 31a and 31b, and hence the overcurrent protections 36a and 36b are configured by hardware.

The power supply relay unit 30 further includes the low voltage monitor 37. The signal from the controller 38 is input to the low voltage monitor 37. The signal from the low voltage monitor 37 is output to the current controller 35a, the current controller 35b, and the controller 38. The low voltage monitor 37 is configured to suppress damages of the switches 31a and 31b when a low voltage (24 V, for example) drops due to, for example, a failure of a booster 42 described later during operation of the power supply relay unit 30 (server 50).

The power supply relay unit 30 further includes the controller 38. The controller 38 is configured to control whether the switches 31a and 31b are on or off so as to supply the DC power from the DC power supply 1 to the server 50. Specifically, the controller 38 transmits a signal to the current controller 35a, and controls whether the switch 31a is on or off via the current controller 35a. In addition, the controller 38 transmits a signal to the current controller 35b, and controls whether the switch 31b is on or off via the current controller 35b. The controller 38 includes a microcomputer, for example.

Signals from the current detectors 34a and 34b, the overcurrent protections 36a and 36b, the low voltage monitor 37, and the switch 33 are input to the controller 38. Information on the power of the shunt resistors 32a and 32b on the input side, information on the power of the switches 31a and 31b on the server 50 side, and an output from a thermistor 39 are input to the controller 38. In addition, a signal is output from the controller 38 to a light source 45 such as an LED.

The controller 38 is configured to be capable of communicating with the server 50 based on the PMBus (registered trademark) standard. The PMBus is a standard for managing a power supply, and communication between devices is performed by exchanging commands. Furthermore, the controller 38 is configured to return preset dummy information on AC input power to the server 50 in response to a request signal from the server 50 for requesting information on the AC input power. Thus, the preset dummy information on the AC input power is returned from the power supply relay unit 30, and hence it is possible to suppress stop of the server 50 due to failure to obtain appropriate information on the AC input power.

The power supply relay unit 30 further includes a regulator 41. The regulator 41 is configured to step down (3.3 V, for example) an input voltage (12 V, for example). The power supply relay unit 30 further includes the booster 42. The booster 42 is configured to boost (24 V, for example) the input voltage (12 V, for example).

### Specific Structure of Power Supply Relay Unit

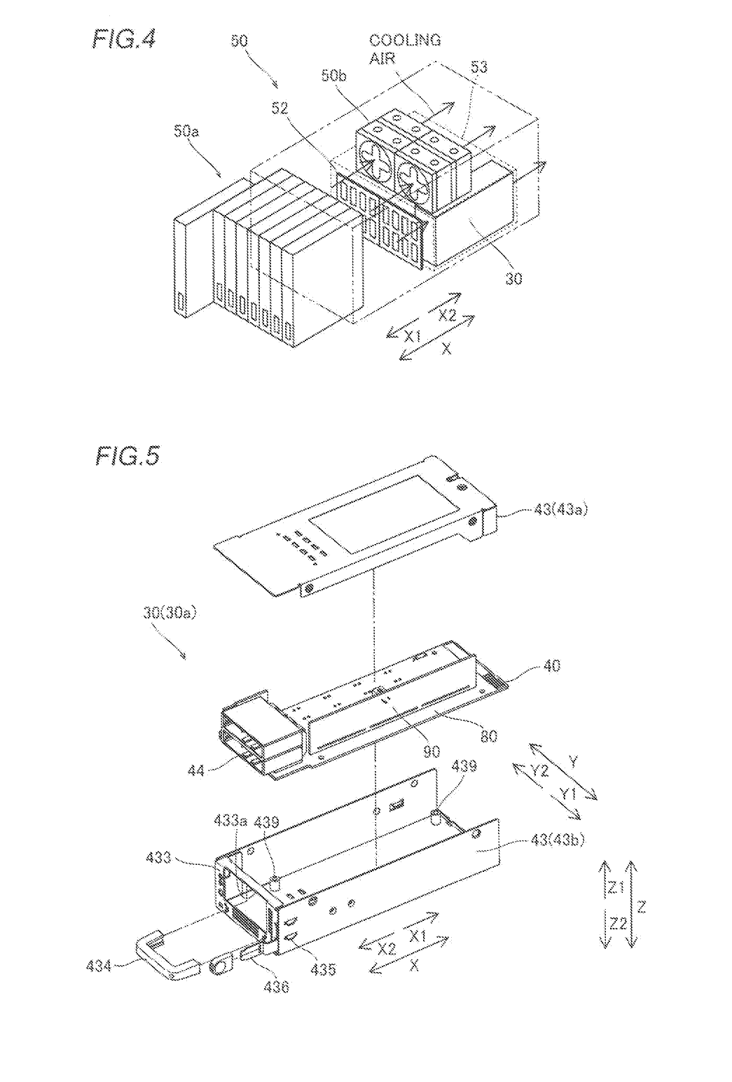

Next, the specific structure of the power supply relay unit 30 according to the present embodiment is described with reference to FIGS. 4 to 10.

As shown in FIG. 4, the server 50 includes the server main body 50a including a blade server, for example, and a cooling fan 50b. The cooling fan 50b is disposed in a rear portion (X2 direction side) of the server main body 50a. Under the cooling fan 50b, a storage 53 (a space surrounded by a dotted line in FIG. 4) capable of housing a server-side power supply unit (not shown) that converts AC power into DC power is provided. According to the present embodiment, the power supply relay unit 30 (power supply relay unit main body 30a) is disposed inside the server 50 through which cooling air generated by the cooling fan 50b flows. Specifically, the power supply relay unit 30 (power supply relay unit main body 30a) is disposed in the storage 53 of the server 50. That is, the power supply relay unit 30 is disposed under the cooling fan 50b.

The power supply relay unit 30 (power supply relay unit main body 30a) is disposed in the storage 53 of the server 50, which is capable of housing a server-side power supply unit, in a state where the connection 40 is directly connected to a server-side connection (backplane) 52 (see FIG. 3). Specifically, the connection 40 is a card edge type connection (see FIG. 5). The term “card edge type” denotes an end of a printed circuit board with contacts to be inserted into a socket. The connection 40 of the power supply relay unit 30 is inserted into the server-side connection 52 of the server 50 to be directly connected to the server-side connection 52. The server main body 50a is also directly connected to the server-side connection (backplane) 52. The server-side connection 52 is an example of a “load-side connection” in the claims.

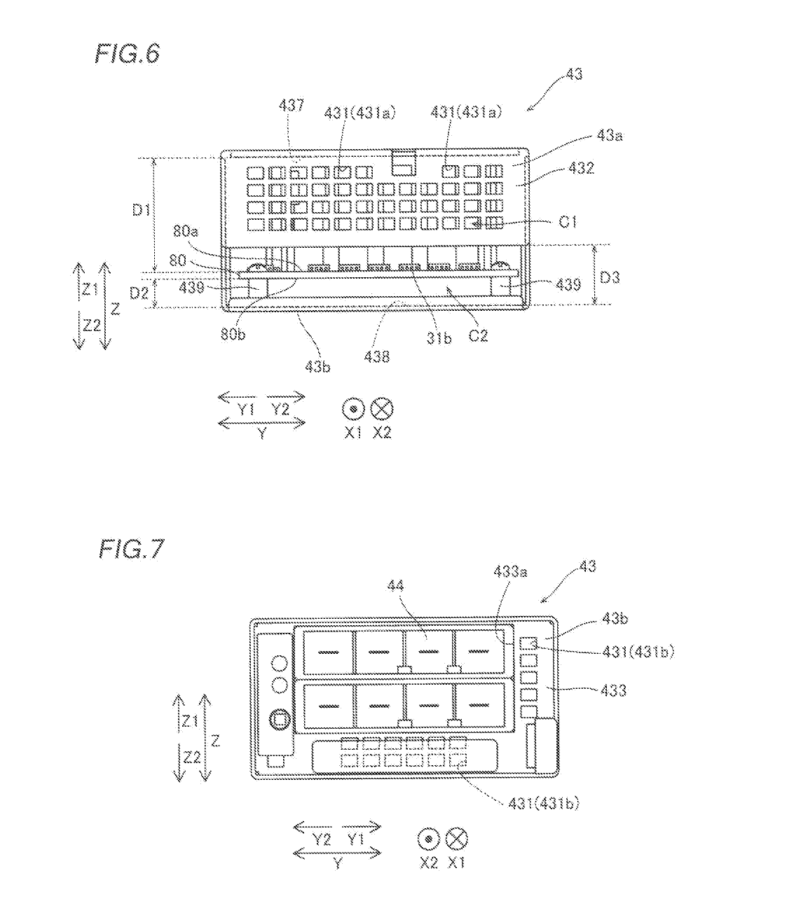

As shown in FIG. 5, the power supply relay unit 30 includes a housing 43 including an upper housing 43a and a lower housing 43b. The housing 43 covers the switch 31a, the switch 31b, the shunt resistor 32a, the shunt resistor 32b, the controller 38, etc. According to the present embodiment, as shown in FIGS. 6 and 7, the housing 43 includes holes 431 through which the cooling air generated by the cooling fan 50b is taken. Specifically, the holes 431 are provided in a side surface 432 of the housing 43 on a first end side (X1 direction side) and a side surface 433 of the housing 43 on a second end side (X2 direction side) in a direction (X direction) in which the switch 31b and the shunt resistor 32b are disposed.

Specifically, as shown in FIG. 6, a plurality of holes 431 (holes 431a) is provided in a matrix in the side surface 432 of the upper housing 43a. As shown in FIG. 7, a plurality of holes 431 (holes 431b) is provided along a Z direction at an end of the side surface 433 of the lower housing 43b on a Y1 direction side, and a plurality of holes 431 (holes 431b) is provided along a Y direction at an end of the side surface 433 of the lower housing 43b on a Z2 direction side. In addition, a substantially rectangular opening 433a for exposing an input connector 44 is provided in the side surface 433 of the lower housing 43b.

As shown in FIG. 5, the housing 43 includes a handle 434 to be gripped by a user when the power supply relay unit 30 is inserted into (or detached from) the storage 53. The housing 43 further includes claws 435 that engage with recesses (not shown) provided in the storage 53 of the server 50. The user operates an operator 436 continuous with the claws 435 such that the claws 435 disengage from the recesses (not shown) provided in the server 50.

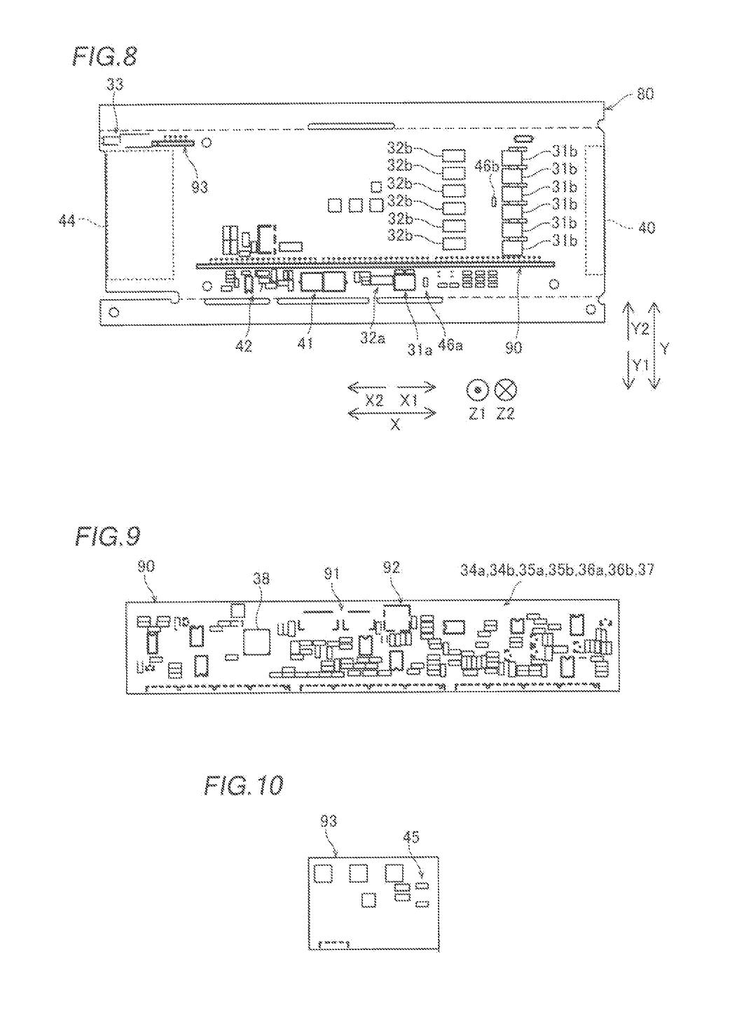

As shown in FIG. 8, the power supply relay unit 30 includes a main substrate 80. On the main substrate 80, the switch 31b and the shunt resistor 32b are disposed. A plurality of switches 31b and a plurality of shunt resistors 32b are disposed along the Y direction on the X1 direction side of the main substrate 80. Furthermore, the switches 31b are disposed on the upstream side (X1 direction side) of the flow of the cooling air generated by the cooling fan 50b relative to the shunt resistors 32b. On the X2 direction side of the main substrate 80, the mechanical switch 33 is disposed.

On the Y1 direction side of the main substrate 80, the switch 31a, the shunt resistor 32a, the regulator 41, and the booster 42 are disposed. A thermistor 46a electrically connected to the switch 31a is disposed adjacent to the switch 31a on the main substrate 80. In addition, a thermistor 46b electrically connected to the switches 31b is disposed between the switches 31b and the shunt resistors 32b on the main substrate 80.

According to this embodiment, as shown in FIG. 6, the housing 43 has a box shape, and a gap C1 through which the cooling air passes is provided between the inner upper surface 437 of the box-shaped housing 43 and the front surface 80a of the main substrate 80 on which the switches 31b and the shunt resistors 32b are disposed. In addition, a gap C2 through which the cooling air passes is provided between the inner lower surface 438 of the box-shaped housing 43 and the back surface 80b of the main substrate 80. Specifically, bosses 439 that protrude upward are provided on the inner lower surface 438 of the housing 43, and the main substrate 80 is disposed on the bosses 439. Thus, the main substrate 80 is provided over the inner lower surface 438 so as to be spaced apart from the inner lower surface 438. Furthermore, the main substrate 80 is disposed under the inner upper surface 437 so as to be spaced apart from the inner upper surface 437. Consequently, the gap C1 and the gap C2 are formed. The distance D1 of the gap C1 in the Z direction is larger than the distance D2 of the gap C2 in the Z direction.

After the cooling air is taken into the housing 43 through the holes 431a, the cooling air passes through the gap C1 and the gap C2 and is discharged through the holes 431b. As shown in FIG. 6, the side surface 432 of the upper housing 43a is formed so as not to reach the inner lower surface 438. That is, the side surface 432 of the upper housing 43a is disposed with a distance D3 from the inner lower surface 438. The cooling air can also be taken into the housing 43 from between the side surface 432 of the upper housing 43a and the inner lower surface 438.

As shown in FIG. 8, the connection 40 connected to the server-side connection 52 of the server 50 is disposed on the X1 direction side of the main substrate 80. Furthermore, the input connector 44 to which the DC power from the DC power supply 1 is input is disposed on the X2 direction side of the main substrate 80.

According to the present embodiment, as shown in FIG. 8, the power supply relay unit 30 includes auxiliary substrates 90 and 93 on which electronic elements that generate less heat than the switches 31b and the shunt resistors 32b are disposed. The auxiliary substrate 90 is disposed on the front surface 80a of the main substrate 80 so as to be substantially perpendicular to the front surface 80a of the main substrate 80 and along the flow of the cooling air (along the X direction). The auxiliary substrate 90 is disposed in contact with the front surface 80a of the main substrate 80.

Specifically, as shown in FIG. 9, the controller 38, a debug/test connector 91, a variable resistor 92, etc. are disposed on the auxiliary substrate 90. Furthermore, the current detectors 34a and 34b, the current controllers 35a and 35b, the overcurrent protections 36a and 36b, the low voltage monitor 37, etc. are disposed on the auxiliary substrate 90. The current detectors 34a and 34b, the current controllers 35a and 35b, the overcurrent protections 36a and 36b, the low voltage monitor 37, the debug/test connector 91, and the variable resistor 92 are examples of an “electronic element” in the claims.

As shown in FIG. 8, the auxiliary substrate 93 is disposed on the Y2 direction side of the input connector 44. As shown in FIG. 10, the light source 45, such as an LED, etc. is disposed on the auxiliary substrate 93. The auxiliary substrate 93 is also disposed in contact with the front surface 80a of the main substrate 80 so as to be substantially perpendicular to the front surface 80a of the main substrate 80 and along the flow of the cooling air (along the X direction). The light source 45 is an example of an “electronic element” in the claims.

According to the present embodiment, as shown in FIG. 8, the auxiliary substrate 90 is disposed on the front surface 80a of the main substrate 80 so as to partition the switches 31b from the switch 31a. Specifically, in a plan view, the switches 31b and the shunt resistors 32b are disposed on the front surface 80a of the main substrate 80 on the Y2 direction side of the auxiliary substrate 90. The switch 31a, the shunt resistor 32a, the regulator 41, and the booster 42 are disposed on the front surface 80a of the main substrate 80 on the Y1 direction side of the auxiliary substrate 90. In addition, in the plan view, the area of a region of the main substrate 80 corresponding to the Y2 direction side of the auxiliary substrate 90 on which the switches 31b and the shunt resistors 32b are disposed is larger than the area of a region of the main substrate 80 corresponding to the Y1 direction side of the auxiliary substrate 90 on which the switch 31a, the shunt resistor 32a, etc. are disposed.

The auxiliary substrate 90 extends from a portion where the switches 31b are disposed to a portion in the vicinity of the input connector 44 on the front surface 80a of the main substrate 80. The main substrate 80, the auxiliary substrate 90, and the auxiliary substrate 93 each have a substantially rectangular shape.

### Cooling Air Flow

As shown in FIG. 4, the cooling air generated by the cooling fan 50b flows from the server main body 50a side (X1 direction side) to the power supply relay unit 30 side (X2 direction side). Thus, the cooling air is taken into the power supply relay unit 30 through the holes 431a (see FIG. 6) of the power supply relay unit 30. Then, the switches 31b, the shunt resistors 32b, etc., which are at a relatively high temperature, are cooled by the cooling air taken into the power supply relay unit 30. The cooling air that has cooled the switches 31b, the shunt resistors 32b, etc. is discharged to the outside of the power supply relay unit 30 through the holes 431b (see FIG. 7) of the power supply relay unit 30.

### Effects of Present Embodiment

According to the present embodiment, the following effects can be obtained.

According to the present embodiment, as hereinabove described, the power supply relay unit main body 30a is disposed inside the server 50 through which the cooling air generated by the cooling fan 50b flows. Thus, even when the cooling fan 50b is not provided in the power supply relay unit main body 30a, the switches 31b and the shunt resistors 32b of the power supply relay unit main body 30a can be cooled by the cooling air generated by the cooling fan 50b included in the server 50. Consequently, it is not necessary to provide the cooling fan 50b in the power supply relay unit main body 30a, and hence it is possible to suppress an increase in the size of the power supply relay unit 30. That is, even when a space (storage 53) in which the power supply relay unit 30 is disposed is limited in size, the power supply relay unit 30 that matches the size of the space can be formed while the power supply relay unit 30 is cooled.

Furthermore, the FIT (average failure rate per unit time) of the cooling fan 50b is relatively large compared with those of the switches 31b and the shunt resistors 32b. That is, the cooling fan 50b is relatively more likely to fail than the switches 31b and the shunt resistors 32b. Therefore, the cooling fan 50b is not provided in the power supply relay unit 30 such that it is possible to suppress shortening of the lifetime of the power supply relay unit 30 due to the failure of the cooling fan 50b. In other words, the cooling fan 50b, which is relatively more likely to fail, is not provided in the power supply relay unit 30, and hence the reliability of the power supply relay unit 30 can be improved.

According to the present embodiment, as hereinabove described, the holes 431 through which the cooling air generated by the cooling fan 50b is taken are provided in the housing 43. Thus, the cooling air generated by the cooling fan 50b can be easily taken into the housing 43 through the holes 431 of the housing 43.

According to the present embodiment, as hereinabove described, the holes 431 are provided in the side surface 432 of the housing 43 at the first end and the side surface 433 of the housing 43 at the second end in the direction in which the switch 31b and the shunt resistor 32b are disposed. Thus, the cooling air taken from the side surface 432 of the housing 43 at the first end is discharged from the side surface 433 of the housing 43 at the second end to the outside of the housing 43 via the switches 31b and the shunt resistors 32b, and hence the switches 31b and the shunt resistors 32b can be effectively cooled.

According to the present embodiment, as hereinabove described, the gap C1 through which the cooling air passes is provided between the inner upper surface 437 of the box-shaped housing 43 and the front surface 80a of the main substrate 80 on which the switches 31b and the shunt resistors 32b are disposed, and the gap C2 through which the cooling air passes is provided between the inner lower surface 438 of the box-shaped housing 43 and the back surface 80b of the main substrate 80. Thus, the cooling air taken into the housing 43 flows over both the front surface 80a and the back surface 80b of the main substrate 80, and hence the switches 31b and the shunt resistors 32b disposed on the main substrate 80 can be efficiently cooled.

According to the present embodiment, as hereinabove described, the power supply relay unit 30 includes the connection 40 directly connected to the server-side connection 52 included in the server and connectable to a server-side power supply unit that converts AC power into DC power. Thus, the power supply relay unit 30 is directly connected to the server-side connection 52 by the connection 40, and hence the power supply relay unit 30 can be easily disposed inside the server 50. Consequently, the cooling air generated by the cooling fan 50b of the server 50 is easily taken into the power supply relay unit 30.

According to the present embodiment, as hereinabove described, the power supply relay unit 30 includes the main substrate 80 on which the switches 31b and the shunt resistors 32b are disposed and the auxiliary substrate 90 on which the electronic elements that generate less heat than the switches 31b and the shunt resistors 32b are disposed. Furthermore, the auxiliary substrate 90 is disposed on the front surface 80a of the main substrate 80 so as to be substantially perpendicular to the front surface 80a of the main substrate 80 and along the flow of the cooling air. Thus, the surface area of the power supply relay unit 30 (main substrate 80) can be reduced unlike the case where all the electronic elements are disposed on the main substrate 80. Furthermore, the auxiliary substrate 90 is disposed on the front surface 80a of the main substrate 80 so as to be substantially perpendicular to the front surface 80a of the main substrate 80 and along the flow of the cooling air, and hence it is possible to suppress obstruction of the flow of the cooling air by the auxiliary substrate 90. That is, the cooling air can smoothly flow over the front surface 80a of the main substrate 80 on which the switches 31b and the shunt resistors 32b that generate a relatively large amount of heat are disposed. Thus, it is possible to suppress a reduction in the cooling efficiency of the cooling air.

According to the present embodiment, as hereinabove described, the auxiliary substrate 90 is disposed on the front surface 80a of the main substrate 80 so as to partition the switches 31b from the switch 31a. Thus, the auxiliary substrate 90 can suppress heat transfer to the switch 31a from the switches 31b that generate a large amount of heat due to the relatively large current I2 flowing therethrough.

According to the present embodiment, as hereinabove described, the power supply relay unit main body 30a is disposed inside the server 50 including the cooling fan 50b. Thus, the cooling fan 50b is provided in advance in the server 50, and hence the switches 31b and the shunt resistors 32b of the power supply relay unit 30 can be cooled by the cooling fan 50b provided in advance.

### Modifications

The embodiment disclosed this time must be considered as illustrative in all points and not restrictive. The range of the present invention is shown not by the above description of the embodiment but by the scope of claims for patent, and all modifications within the meaning and range equivalent to the scope of claims for patent are further included.

For example, while the example in which the power supply relay unit is disposed under the cooling fan has been shown in the aforementioned embodiment, the present invention is not restricted to this. According to the present invention, the power supply relay unit may not be disposed under the cooling fan as long as the power supply relay unit is disposed in a path through which the cooling air generated by the cooling fan flows. For example, the power supply relay unit may be disposed on the front side of the cooling fan (the side on which the cooling air is taken) or on the rear side of the cooling fan (the side on which the cooling air is discharged).

While the example in which the plurality of holes through which the cooling air is taken into the housing is provided has been shown in the aforementioned embodiment, the present invention is not restricted to this. For example, a relatively large hole (or notch) may be provided to take the cooling air into the housing.

While the example in which the holes are provided in the side surface of the housing on the X1 direction side and the side surface of the housing on the X2 direction side has been shown in the aforementioned embodiment, the present invention is not restricted to this. For example, the holes may be provided in a portion other than the side surface of the housing on the X1 direction side and the side surface of the housing on the X2 direction side.

While the example in which the distance (D1, see FIG. 6) between the inner upper surface of the housing and the front surface of the main substrate is larger than the distance (D2) between the inner lower surface of the housing and the back surface of the main substrate has been shown in the aforementioned embodiment, the present invention is not restricted to this. For example, the distance (D1) between the inner upper surface of the housing and the front surface of the main substrate may be equal to or smaller than the distance (D2) between the inner lower surface of the housing and the back surface of the main substrate.

While the example in which the auxiliary substrate is disposed in contact with the front surface of the main substrate has been shown in the aforementioned embodiment, the present invention is not restricted to this. For example, the auxiliary substrate and the main substrate may be spaced apart from each other.

While the example in which the present invention is applied to the server as a load has been shown in the aforementioned embodiment, the present invention is not restricted to this. For example, the present invention may be applied to a load other than the server.

While the example in which after the cooling air is taken into the housing 43 through the holes 431a, the cooling air is discharged through the holes 431b has been shown in the aforementioned embodiment, the present invention is not restricted to this. For example, the cooling air may be discharged through the holes 431a after being taken into the housing 43 through the holes 431b.

While the example in which the cooling air flows in the X direction from the X1 direction side to the X2 direction side, as shown in FIG. 4 has been shown in the aforementioned embodiment, the present invention is not restricted to this. For example, the cooling air may flow in a direction other than the X direction. Alternatively, the cooling air not only may flow in a specific direction (such as the X direction) but also may swirl in a plurality of directions.

What is claimed is:

1. A power supply relay unit provided between a DC power supply including a power supply unit that converts AC power into DC power and a battery unit that stores the DC power obtained by conversion by the power supply unit, and a load including a cooling fan, comprising:
a power supply relay unit main body including a first switch to which the DC power from the DC power supply is input and a resistor provided between the DC power supply and the first switch and configured to detect a current that flows from the DC power supply to the first switch, the power supply relay unit main body being adapted to be disposed inside the load through which cooling air generated by the cooling fan flows,
a main substrate on which the first switch and the resistor are disposed; and
an auxiliary substrate on which an electronic element that generates less heat than the first switch and the resistor is adapted to be disposed.

2. The power supply relay unit according to claim 1, further comprising a housing that covers the first switch and the resistor,
wherein the housing includes a hole through which the cooling air generated by the cooling fan is adapted to be taken.

3. The power supply relay unit according to claim 2, wherein the housing further includes a first side surface on a first end side and a second side surface on a second end side in a direction in which the first switch and the resistor are disposed, holes being provided in the first and second surfaces.

4. The power supply relay unit according to claim 2, wherein the housing is box-shaped, and includes an inner upper surface and an inner lower surface, and
the main substrate includes a front surface on which the first switch and the resistor are disposed, and a back surface, and
wherein a gap through which the cooling air passes is provided between the inner upper surface of the box-shaped housing and the front surface of the main substrate, and a gap through which the cooling air passes is provided between the inner lower surface of the box-shaped housing and the back surface of the main substrate.

5. The power supply relay unit according to claim 1, further comprising a power supply relay unit-side connection adapted to be directly connected to a load-side connection included in the load and connectable to a load-side power supply unit that converts AC power into DC power.

6. The power supply relay unit according to claim 1, wherein the auxiliary substrate is disposed on a front surface of the main substrate so as to be substantially perpendicular to the front surface of the main substrate.

7. The power supply relay unit according to claim 6, further comprising a second switch disposed on the main substrate adapted to be turned on to supply a first current to the load and activate a load-side controller of the load,
wherein the first switch is configured to, after the load-side controller of the load is activated, be turned on based on a request signal from the load-side controller of the load for requesting power supply to supply a second current larger than the first current to the load, and
the auxiliary substrate is disposed on the front surface of the main substrate so as to partition the first switch from the second switch.

8. The power supply relay unit according to claim 1, wherein the power supply relay unit main body is adapted to be disposed inside a server as the load through which the cooling air generated by the cooling fan flows.
